(19) United States
(12) Patent Application Publication
(10) Pub. No.: US 2026/0255639 A1
(43) Pub. Date: Aug. 27, 2026

(54) SEMICONDUCTOR DEVICE

(71) Applicant: Samsung Electronics Co., Ltd., Suwon-si (KR)

(72) Inventors: Jonghak Kim, Suwon-si (KR); Young Jun Byun, Suwon-si (KR); Gyutae Jang, Suwon-si (KR); Sehee Jang, Suwon-si (KR)

(73) Assignee: Samsung Electronics Co., Ltd., Suwon-si (KR)

(21) Appl. No.: 19/332,391

(22) Filed: Sep. 18, 2025

(30) Foreign Application Priority Data
Feb. 27, 2025 (KR) 10-2025-0026208
Mar. 10, 2025 (KR) 10-2025-0030885

(51) Int. Cl. H10D 62/10; H10D 30/01; H10D 30/66; H10D 62/00; H10D 62/832

(52) U.S. Cl. CPC H10D 62/111; H10D 30/0291; H10D 30/66; H10D 62/052; H10D 62/8325

(57) ABSTRACT

According to embodiments, a semiconductor device comprising: a substrate including a first surface and a second surface opposing one another; a first conductivity type semiconductor layer positioned on the first surface of the substrate; a second conductivity type doped well region positioned within the first conductivity type semiconductor layer; a pillar layer positioned between the substrate and the second conductivity type doped well region and having the second conductivity type; a gate electrode positioned on the first conductivity type semiconductor layer; a gate insulating layer positioned between the first conductivity type semiconductor layer and the gate electrode; a source electrode positioned on the second conductivity type doped well region; and a drain electrode positioned on the second surface of the substrate, the pillar layer includes a first pillar pattern including a semiconductor material having a first energy band gap, and a second pillar pattern positioned between the first pillar pattern and the first conductivity type semiconductor layer, the second pillar pattern including a semiconductor material having a second energy band gap greater than the first energy band gap.

### CROSS-REFERENCE TO RELATED APPLICATION

This present application claims priority to and the benefit under 35 U.S.C. § 119(a)-(d) of Korean Patent Application No. 10-2025-0026208 filed with the Korean Intellectual Property Office on Feb. 27, 2025, and Korean Patent Application No. 10-2025-0030885 filed with the Korean Intellectual Property Office on Mar. 10, 2025, the entire disclosure of which are incorporated herein by reference.

### FIELD

The present disclosure relates to a semiconductor device.

### BACKGROUND

In modern society, semiconductor devices are closely related to our daily lives. In particular, the importance of power semiconductor devices used in various fields such as transportation (e.g. electric vehicles, railways, and electric trams), renewable energy systems (e.g. solar power generation and wind power generation), and mobile devices is gradually increasing. Power semiconductor devices are semiconductor devices used to handle high voltage or high current, and perform functions such as power conversion and control in large power systems or high-power electronic devices. Power semiconductor devices have high durability and the ability to handle high power, allowing them to handle large amounts of current and withstand high voltages. For example, power semiconductor devices may handle voltages from hundreds to thousands of volts and currents from tens to thousands of amperes. Power semiconductor devices may improve the efficiency of electrical energy by minimizing power loss. Additionally, power semiconductor devices may operate stably even in environments such as high temperatures.

These power semiconductor devices may be classified by material, for example, SiC based and GaN based power semiconductor devices are available. By manufacturing power semiconductor devices using SiC or GaN instead of existing silicon wafers (Si wafers), the shortcomings of silicon, such as unstable characteristics at high temperatures, may be complemented. SiC power semiconductor devices have high temperature resistance and low power loss, making them suitable for electric vehicles and renewable energy systems. Among them, semiconductor devices with a super junction structure are widely used to improve the trade-off between the forward characteristics and breakdown voltage of power semiconductor devices.

### SUMMARY

The embodiments are intended to provide a semiconductor device whose reliability may be improved.

According to embodiments, semiconductor device comprising: a substrate including a first surface and a second surface opposing one another; a first conductivity type semiconductor layer positioned on the first surface of the substrate; a second conductivity type doped well region positioned within the first conductivity type semiconductor layer; a pillar layer positioned between the substrate and the second conductivity type doped well region and having the second conductivity type; a gate electrode positioned on the first conductivity type semiconductor layer; a gate insulating layer positioned between the first conductivity type semiconductor layer and the gate electrode; a source electrode positioned on the second conductivity type doped well region; and a drain electrode positioned on the second surface of the substrate, the pillar layer includes a first pillar pattern including a semiconductor material having a first energy band gap, and a second pillar pattern positioned between the first pillar pattern and the first conductivity type semiconductor layer, the second pillar pattern including a semiconductor material having a second energy band gap greater than the first energy band gap.

According to embodiments, semiconductor device comprising: a substrate including a first surface and a second surface opposing one another; a first conductivity type semiconductor layer positioned on the first surface of the substrate and including a first element that is a semiconductor material and a second element that is different from the first element; a second conductivity type doped well region positioned within the first conductivity type semiconductor layer; a pillar layer positioned within the first conductivity type semiconductor layer and extending from the lower surface of the second conductivity type doped well region toward the substrate, the pillar layer having the second conductivity type and including the first element and the second element; a gate electrode positioned on the first conductivity type semiconductor layer; a gate insulating layer positioned between the first conductivity type semiconductor layer and the gate electrode; a source electrode positioned on the second conductivity type doped well region; and a drain electrode positioned on the second surface of the substrate, the pillar layer includes a first pillar pattern, and a second pillar pattern positioned between the first pillar pattern and the first conductivity semiconductor layer, wherein a content (at %) of the second element in the second pillar pattern is greater than a content (at %) of the second element in the first pillar pattern.

According to embodiments, semiconductor device comprising: a substrate including a first surface and a second surface opposing one another; a first conductivity type semiconductor layer including Si and C, positioned on the first surface of the substrate; a second conductivity type doped well region positioned within the first conductivity type semiconductor layer; a pillar layer positioned between the substrate and the second conductivity type doped well region, the pillar layer having the second conductivity type and including Si and C; a gate electrode positioned on the first conductivity type semiconductor layer; a gate insulating layer positioned between the first conductivity type semiconductor layer and the gate electrode; a source electrode positioned on the second conductivity type doped well region; and a drain electrode positioned on the second surface of the substrate, wherein the pillar layer includes a first pillar pattern including Si at a first content (at %), and a second pillar pattern positioned between the first pillar pattern and the first conductivity type semiconductor layer, the second pillar pattern including Si at a second content (at %) smaller than the first content (at %), wherein the second content (at %) in the second pillar pattern is greater than or equal to a Si content (at %) in the first conductivity type semiconductor layer.

According to embodiments, a method for manufacturing a semiconductor device includes the steps of forming a first conductivity type semiconductor layer on a first surface of a substrate, forming a trench in the first conductivity type semiconductor layer, forming a pillar layer in the trench, the pillar layer including: a second pillar pattern including a semiconductor material having a second energy band gap; a first pillar pattern including a semiconductor material having a first energy band gap smaller than the second energy band gap; and having the second conductivity type, forming a second conductivity type doped well region on the pillar layer, forming a gate insulating layer and a gate electrode on the second conductivity type doped well region, forming a source electrode on the second conductivity type doped well region, and forming a drain electrode on a second surface of the substrate opposite to the first surface.

The step of forming the pillar layer may form the second pillar pattern by using lateral epitaxial growth, using the first conductivity type semiconductor layer as a seed.

The step of forming the pillar layer may include the steps of forming a second pillar pattern material layer on the inner sidewall and bottom surface of the trench, removing at least a portion of the second pillar pattern material layer to expose the bottom surface of the trench, and forming a first pillar pattern filling the inside of the trench.

The first conductivity type semiconductor layer may include a material having a third energy band gap that is equal to or greater than the second energy band gap.

The first pillar pattern and the second pillar pattern extend from a lower surface of the second conductivity type doped well region toward the substrate, and a lower surface of the first pillar pattern may be in contact with the first conductivity type semiconductor layer.

The first pillar pattern and the second pillar pattern include a first element and a second element, and a content (at %) of the first element in the second pillar pattern may be less than a content (at %) of the first element in the first pillar pattern.

The first conductivity type semiconductor layer includes the first element and the second element, and the content (at %) of the first element in the second pillar pattern may be greater than or equal to the content (at %) of the first element in the first conductivity type semiconductor layer.

The first element may include Si, and the second element may include C.

The first conductivity type semiconductor layer includes the first element and the second element, and the second pillar pattern includes the first element, the second element, and a third element that is different from the first element and the second element, and a content (at %) of the second element in the second pillar pattern may be less than or equal to a content (at %) of the second element in the first conductivity type semiconductor layer.

The first element may include Si, the second element may include C, and the third element may include Ge.

The second pillar pattern includes the first element, the second element, and the third element, wherein a content (at %) of the second element in the second pillar pattern may be greater than a content (at %) of the second element in the first pillar pattern.

A semiconductor device according to the embodiments may have improved reliability of the semiconductor device.

### BRIEF DESCRIPTION OF THE DRAWINGS

FIG. 1 is a cross-sectional view showing a semiconductor device according to embodiments.

FIG. 2 is a graph illustrating the contents of materials constituting the pillar layer and the first conductivity type semiconductor layer of a semiconductor device according to embodiments.

FIGS. 3 to 8 are graphs illustrating the contents of materials constituting a pillar layer and a first conductivity type semiconductor layer of a semiconductor device according to some embodiments.

FIG. 9 is a cross-sectional view illustrating a semiconductor device according to some embodiments.

FIGS. 10 to 12 are graphs illustrating the contents of materials constituting the pillar layer and the first conductivity type semiconductor layer of embodiments of FIG. 9.

FIG. 13 is a cross-sectional view illustrating a semiconductor device according to some embodiments.

FIG. 14 is an enlarged cross-sectional view of the SI area of FIG. 13.

FIGS. 15 to 23 are intermediate process cross-sectional views showing a method for manufacturing a semiconductor device according to embodiments.

### DETAILED DESCRIPTION

Hereinafter, various embodiments will be described in detail with reference to the attached drawings so that a person having ordinary skill in the art to which the present invention pertains may easily implement the invention. The present invention may be embodied in many different forms and is not limited to the embodiments described herein.

In order to clearly explain the present invention, parts irrelevant to the description are omitted, and the same reference numerals are used for identical or similar components throughout the specification.

In addition, the size and the thickness of each component shown in the drawing are arbitrarily shown for convenience of explanation, so the present invention is not necessarily limited to what is shown. To clearly represent the various layers and areas in the drawing, the thickness is enlarged and shown. And in the drawing, for convenience of explanation, the thickness of some layers and areas is exaggerated.

Also, when we say that a part, such as a layer, membrane, region, or plate, is “over” or “on” another part, this includes not only cases where it is “directly over” the other part, but also cases where there are other parts in between. Conversely, when we say that a part is “directly above” another part, we mean that there is no other part in between. Also, being “above” or “on” a reference part means being located above or below the reference part, and does not necessarily mean being located “above” or “on” the opposite direction of gravity.

Additionally, throughout the specification, whenever a part is said to “include” a component, this does not mean that it excludes other components, but rather that it may include other components, unless otherwise specifically stated.

Additionally, throughout the specification, when we say “in plan”, we mean when the target portion is viewed from above, and when we say “in cross section”, we mean when the target portion is viewed from the side in a cross-section cut vertically.

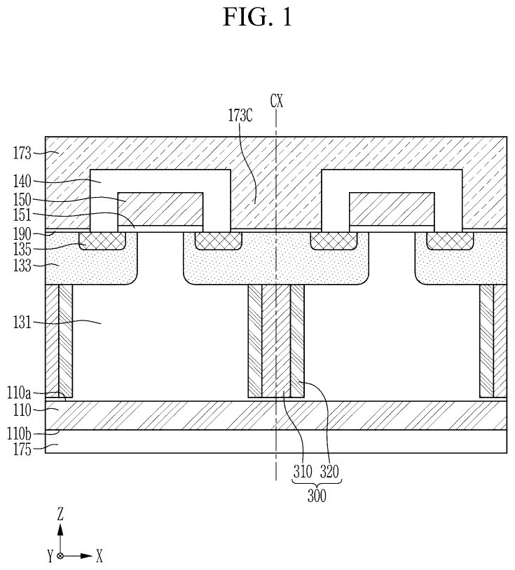

Hereinafter, referring to FIG. 1, a semiconductor device according to embodiments will be described.

FIG. 1 is a plan view showing a semiconductor device according to embodiments.

Referring to FIG. 1, a semiconductor device according to embodiments includes a substrate 110, a first conductivity type semiconductor layer 131 positioned on a first surface 110a of the substrate 110, a second conductivity type doped well region 133 positioned within the first conductivity type semiconductor layer 131, a second conductivity type pillar layer 300 positioned between the substrate 110 and the second conductivity type doped well region 133, a gate electrode 150 positioned on the first conductivity type semiconductor layer 131, a gate insulating layer 151 positioned between the first conductivity type semiconductor layer 131 and the gate electrode 150, a source electrode 173 positioned on the second conductivity type doped well region 133, and a drain electrode 175 positioned on the second surface 110b of the substrate 110.

The substrate 110 may be a semiconductor substrate including SiC. For example, the substrate 110 may be made of a 4H SiC substrate. In some cases, the substrate 110 may be made of a 3C SiC substrate, a 6H SiC substrate, etc. The substrate 110 may be doped with first conductivity type impurities. For example, the first conductivity type impurity may be an n-type impurity. In other words, the substrate 110 may be doped as n-type. The substrate 110 may be heavily doped as n-type. The resistivity of the substrate 110 may be between about 0.005 Ωcm and about 0.035 Ωcm. The thickness of the substrate 110 may be from about 10 μm to about 700 μm. The material, doping type, doping concentration, resistivity, thickness, etc. of the substrate 110 are not limited thereto and may be variously changed.

The substrate 110 may include a first surface 110a and a second surface 110b opposing one another. For example, the first surface 110a of the substrate 110 may mean the upper surface of the substrate 110, and the second surface 110b of the substrate 110 may mean the lower surface of the substrate 110.

The first conductivity type semiconductor layer 131 may be positioned on the first surface 110a of the substrate 110, i.e., the upper surface. The lower surface of the first conductivity type semiconductor layer 131 may be in contact with the first surface 110a of the substrate 110. However, example embodiments are not limited thereto, and other layers may be additionally positioned between the substrate 110 and the first conductivity type semiconductor layer 131. The first conductivity type semiconductor layer 131 may be an epitaxial layer formed from the substrate 110 using an epitaxial growth method. The first conductivity type semiconductor layer 131 may include SiC. For example, the first conductivity type semiconductor layer 131 may include 4H SiC. The first conductivity type semiconductor layer 131 may be doped as n-type. The first conductivity type semiconductor layer 131 may be lightly doped as n-type. The doping concentration of the first conductivity type semiconductor layer 131 may be lower than the doping concentration of the substrate 110. The doping concentration of the first conductivity type semiconductor layer 131 may be about 1*10¹⁵cm⁻³ or more and about 1*10¹⁷cm⁻³ or less. The thickness of the first conductivity type semiconductor layer 131 may be about 1 μm or more and about 13 μm or less.

The second conductivity type doped well region 133 may be positioned within the first conductivity type semiconductor layer 131. The second conductivity type doped well region 133 may be positioned on top of the first conductivity type semiconductor layer 131. In embodiments, at least a portion of an upper surface of the second conductivity type doped well region 133 may overlap with the gate electrode 150, which will be described later, and a gate insulator 151, which will be described later, in the third direction (Z direction). Here, the third direction (Z direction) may mean a vertical direction perpendicular to the thickness direction of the substrate 110 and/or the first surface 110a of the substrate 110.

In embodiments, the second conductivity type doped well region 133 may be used as a channel of a transistor constituting a semiconductor device. For example, a portion of the second conductivity type doped well region 133 adjacent to the gate electrode 150, which will be described later, may function as a channel of the transistor. In other words, a current path may be formed from the source electrode 173 toward the drain electrode 175 in at least a region of the second conductivity type doped well region 133. For convenience of explanation, below, the portion of the second conductivity type doped well region 133 adjacent to the gate electrode 150, which functions as a channel of the transistor, is referred to as the channel region.

The second conductivity type doped well region 133 may extend from the upper surface of the first conductivity type semiconductor layer 131 toward the lower surface of the first conductivity type semiconductor layer 131. The second conductivity type doped well region 133 may extend in the third direction (Z direction) from the upper surface of the first conductivity type semiconductor layer 131. The second conductivity type doped well region 133 may be formed in at least a portion of the first conductivity type semiconductor layer 131 by ion implantation, but example embodiments are not limited thereto.

The second conductivity type doped well region 133 may include SiC. For example, the second conductivity type doped well region 133 may include 4H SiC. The second conductivity type doped well region 133 may be doped as p-type. The second conductivity type doped well region 133 may be lightly doped as p-type. The doping concentration of the second conductivity type doped well region 133 may be between about 1*10¹⁷ cm⁻³ and about 1*10¹⁹ cm⁻³. The material, doping type, doping concentration, etc. of the second conductivity type doped well region 133 are not limited thereto and may be changed in various ways.

The pillar layer 300 may be positioned within the first conductivity type semiconductor layer 131. The pillar layer 300 may be positioned on the first surface 110a of the substrate 110. The pillar layer 300 may be positioned between the substrate 110 and the second conductivity type doped well region 133. The pillar layer 300 may overlap with the second conductivity type doped well region 133 in the third direction (Z direction) and may not overlap with the gate electrode 150 described later in the third direction (Z direction).

The pillar layer 300 may extend in the third direction (Z direction). For example, the pillar layer 300 may extend in the third direction (Z direction) from the lower surface of the second conductivity type doped well region 133 toward the substrate 110. The pillar layer 300 may be positioned spaced apart from the substrate 110. The pillar layer 300 may be positioned spaced apart from the substrate 110 in the third direction (Z direction). The lower surface of the pillar layer 300 may be positioned at a higher level than the first surface 110a of the substrate 110. A first conductivity type semiconductor layer 131 may be positioned between the pillar layer 300 and the substrate 110. At least a portion of the pillar layer 300 may be surrounded by the first conductivity type semiconductor layer 131. For example, the side surface and bottom surface of the pillar layer 300 may be surrounded by the first conductivity type semiconductor layer 131. The side surface and bottom surface of the pillar layer 300 may be in contact with the first conductivity type semiconductor layer 131, but example embodiments are not limited thereto.

A semiconductor device according to embodiments may include a plurality of pillar layers 300 arranged spaced apart along a first direction (X direction) within a first conductivity type semiconductor layer 131. The plurality of pillar layers 300 may be positioned directly beneath the second conductivity type doped well region 133. The first conductivity type semiconductor layer 131 may be positioned between the plurality of pillar layers 300. The lengths of each of the plurality of pillar layers 300 in the third direction (Z direction) may be substantially the same, but example embodiments are not limited thereto.

The pillar layer 300 may include a semiconductor material. The pillar layer 300 may include the same material as the first conductivity type semiconductor layer 131 and the second conductivity type doped well region 133. For example, the pillar layer 300 may include a first element that is a semiconductor element and a second element that is different from the first element. Here, the first element may include Si, and the second element may include C. The pillar layer 300 may be SiₓC₁₋ₓ (0<x<1). For example, the first conductivity type semiconductor layer 131, the second conductivity type doped well region 133, and the pillar layer 300 may include SiₓC₁₋ₓ (0<x<1). The pillar layer 300 may be an epitaxial layer formed from the first conductivity type semiconductor layer 131 using an epitaxial growth method. For example, the pillar layer 300 layer may be made of a superlattice layer. If the pillar layer 300 is composed of a superlattice layer, the difference in lattice constant and thermal expansion coefficient with the surrounding material layers may be alleviated. The pillar layer 300 may have a second conductivity type. The pillar layer 300 may be doped with second conductivity type impurities. Here, the second conductivity type may be p-type.

However, this is not limited thereto, and as another example, the first conductivity type semiconductor layer 131, the second conductivity type doped well region 133, and the pillar layer 300 may include GaN. In this case, the first element may be Ga and the second element may be N.

The pillar layer 300 may include multiple layers having different energy band gaps. For example, the pillar layer 300 may include a first pillar pattern 310 including a semiconductor material having a first energy band gap and a second pillar pattern 320 including a semiconductor material having a second energy band gap larger than the first energy band gap.

The first pillar pattern 310 may be positioned within the first conductivity type semiconductor layer 131. The first pillar pattern 310 may be positioned on the first surface 110a of the substrate 110. The first pillar pattern 310 may be positioned between the substrate 110 and the second conductivity type doped well region 133. The first pillar pattern 310 may overlap with the second conductivity type doped well region 133 in the third direction (Z direction), and may not overlap with the gate electrode 150 described later in the third direction (Z direction). The first pillar pattern 310 may be positioned at the center portion of the pillar layer 300.

The first pillar pattern 310 may be extended in the third direction (Z direction). For example, the first pillar pattern 310 may extend in the third direction (Z direction) from the lower surface of the second conductivity type doped well region 133 toward the substrate 110. The first pillar pattern 310 may be positioned spaced apart from the substrate 110 in the third direction (Z direction). The first conductivity type semiconductor layer 131 may be positioned between the first pillar pattern 310 and the substrate 110. The lower surface of the first pillar pattern 310 may be in contact with the first conductivity type semiconductor layer 131, but example embodiments are not limited thereto.

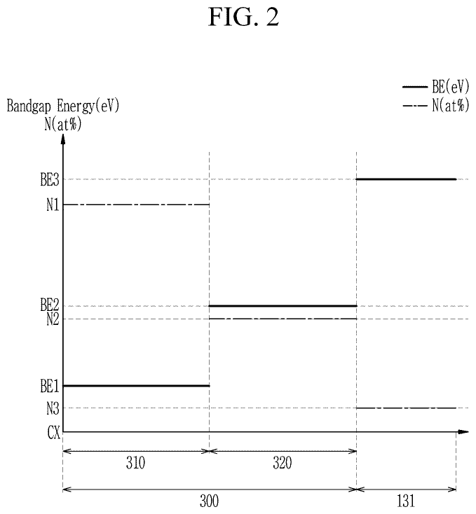

The first pillar pattern 310 may include a semiconductor material. The first pillar pattern 310 may include the same material as the first conductivity type semiconductor layer 131 and the second conductivity type doped well region 133. For example, the first pillar pattern 310 may include a first element and a second element. Here, the first element may be Si and the second element may be C, but example embodiments are not limited thereto. The first pillar pattern 310 may be SiₓC₁₋ₓ (0<x<1). In this case, the semiconductor material constituting the first pillar pattern 310 may have the first energy band gap (se BE1 of FIG. 2). A description of this will be given later, referring to FIG. 2.

The second pillar pattern 320 may be positioned between the first pillar pattern 310 and the first conductivity type semiconductor layer 131. The second pillar pattern 320 may be positioned on the side surface of the first pillar pattern 310. For example, the second pillar pattern 320 may be positioned on opposite side surfaces of the first pillar pattern 310, but example embodiments are not limited thereto. Opposite side surfaces of the first pillar pattern 310 may be covered by the second pillar pattern 320. The side surface of the first pillar pattern 310 may be in contact with the second pillar pattern 320, but example embodiments are not limited thereto. The second pillar pattern 320 may be positioned on the outer portion of the pillar layer 300.

The second pillar pattern 320 may be positioned on the first surface 110a of the substrate 110. The second pillar pattern 320 may be positioned between the substrate 110 and the second conductivity type doped well region 133. The second pillar pattern 320 may overlap with the second conductivity type doped well region 133 in the third direction (Z direction) and may not overlap with the gate electrode 150, which will be described later, in the third direction (Z direction). The second pillar pattern 320 may be extended in the third direction (Z direction). For example, the second pillar pattern 320 may extend in the third direction (Z direction) from the lower surface of the second conductivity type doped well region 133 toward the substrate 110. The second pillar pattern 320 may be positioned spaced apart from the substrate 110 in the third direction (Z direction). The first conductivity type semiconductor layer 131 may be positioned between the second pillar pattern 320 and the substrate 110. The upper surface of the second pillar pattern 320 may be in contact with the second conductivity type doped well region 133, but example embodiments are not limited thereto. The lower surface of the second pillar pattern 320 may be in contact with the first conductivity type semiconductor layer 131, but example embodiments are not limited thereto.

The second pillar pattern 320 may include a semiconductor material. The second pillar pattern 320 may include the same material as the first pillar pattern 310. The second pillar pattern 320 may include the same material as the first conductivity type semiconductor layer 131 and the second conductivity type doped well region 133. For example, the second pillar pattern 320 may include a first element and a second element. Here, the first element may be Si and the second element may be C, but example embodiments are not limited thereto. The second pillar pattern 320 may be SiₓC_{1-x (}0<x<1). In this case, the semiconductor material constituting the second pillar pattern 320 may have a second energy band gap (see BE2 of FIG. 2). A description of this will be given later, referring to FIG. 2.

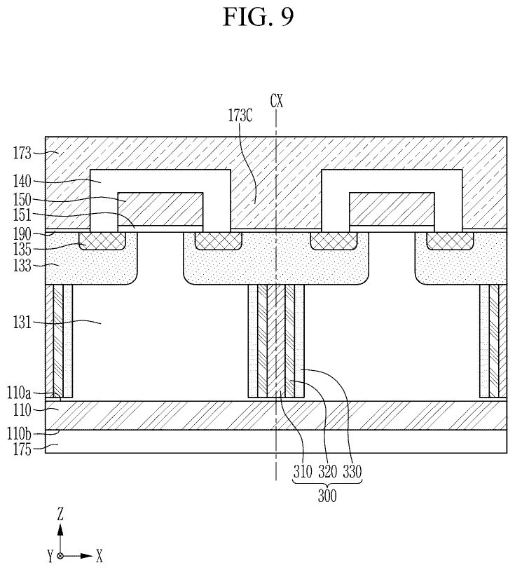

Although FIG. 1 illustrates that the pillar layer 300 includes two pillar patterns 310 and 320, the number of pillar patterns 310 and 320 is not limited thereto. For example, as in embodiments of FIG. 9, the pillar layer 300 may include three pillar patterns 310 and 320. As another example, the pillar layer 300 may include four or more pillar patterns 310 and 320. A description of this will be given later, referring to FIG. 9.

The gate electrode 150 may be positioned on the first conductivity type semiconductor layer 131. The gate electrode 150 may be spaced apart from the first conductivity type semiconductor layer 131. For example, the gate electrode 150 may be spaced apart from the first conductivity type semiconductor layer 131 in the third direction (Z direction) by the gate insulating layer 151. A semiconductor device according to embodiments may have a planar-shaped gate structure. In the semiconductor device according to embodiments, the gate electrode 150 has a flat plate shape with an upper surface and a lower surface, and the lower surface of the gate electrode 150 may be positioned at a level higher than the uppermost surface of the first conductivity type semiconductor layer 131. However, example embodiments are not limited thereto, and the semiconductor device according to embodiments may have a trench-shaped gate structure. For example, in a semiconductor device according to embodiments, a trench having a predetermined depth is formed in the first conductivity type semiconductor layer 131, and the gate electrode 150 may be positioned inside the trench spaced apart from the first conductivity type semiconductor layer 131 in a third direction (Z direction). Additionally, the gate electrode 150 may be positioned spaced apart from the first conductivity type semiconductor layer 131 in the first direction (X direction). The gate electrode 150 may overlap the second conductivity type doped well region 133 in the third direction (Z direction).

The gate electrode 150 may include a conductive material. For example, the gate electrode 150 may include polysilicon doped with impurities. As another example, the gate electrode 150 may include a metal, a metal alloy, a conductive metal nitride, a metal silicide, a doped semiconductor material, a conductive metal oxide, a conductive metal oxynitride, or a combination thereof. The gate electrode 150 may be formed of a single layer or multiple layers.

The gate insulating layer 151 may be positioned between the first conductivity type semiconductor layer 131 and the gate electrode 150. The gate insulating layer 151 may be positioned under the gate electrode 150 and cover the lower surface of the gate electrode 150. The gate electrode 150 may be insulated from the first conductivity type semiconductor layer 131 by the gate insulating layer 151. The thickness of the gate insulating layer 151 may be almost constant. In embodiments, the gate insulating layer 151 may overlap the second conductivity type doped well region 133 in the third direction (Z direction). The lower surface of the gate insulating layer 151 may be in contact with the second conductivity type doped well region 133, but example embodiments are not limited thereto.

The gate insulating layer 151 may include an insulating material. For example, the gate insulating layer 151 may include SiO₂. However, example embodiments are not limited thereto, and the material of the gate insulating layer 151 may be changed in various ways. As another example, the gate insulator 151 may include SiN, SiON, SiC, SiCN or a combination thereof. The gate insulating layer 151 may be formed of a single layer or multiple layers.

A semiconductor device according to embodiments may further include a first conductivity type doped layer 135 positioned within a second conductivity type doped well region 133.

The first conductivity type doped layer 135 may be positioned within the second conductivity type doped well region 133. The first conductivity type doped layer 135 is positioned on top of the first conductivity type semiconductor layer 131 and may have an upper surface that is in contact with the lower surface of the silicide layer 190 connected to the source electrode 173 to be described later. In embodiments, at least a portion of the upper surface of the first conductivity type doped layer 135 may be in contact with, but example embodiments are not limited thereto, the lower surface of the silicide layer 190, which will be described later. As another example, at least a portion of the upper surface of the first conductivity type doped layer 135 may be in contact with the lower surface of the source electrode 173. The first conductivity type doped layer 135 may be buried within the second conductivity type doped well region 133.

In embodiments, the first conductivity type doped layer 135 may extend in the third direction (Z direction) from the upper surface of the first conductivity type semiconductor layer 131. In this case, the thickness of the first conductivity type doped layer 135 along the third direction (Z direction) may be smaller than the thickness of the second conductivity type doped well region 133 along the third direction (Z direction). The first conductivity type doped layer 135 may be formed in at least a portion of the second conductivity type doped well region 133 by ion implantation.

The first conductivity type doped layer 135 may include SiC. For example, the first conductivity type doped layer 135 may include 4H SiC. The first conductivity type doped layer 135 may be n-type doped. The first conductivity type doped layer 135 may form an ohmic contact with the source electrode 173. For this purpose, the first conductivity type doped layer 135 may be highly doped as n-type. In embodiments, the doping concentration of the first conductivity type doped layer 135 may be higher than the doping concentration of the first conductivity type semiconductor layer 131. The doping concentration of the first conductivity type doped layer 135 may be between about 1*10¹⁸ cm⁻³ and about 5*10²⁰ cm⁻³. The material, doping type, doping concentration, etc. of the first conductivity type doped layer 135 are not limited thereto and may be changed in various ways.

A semiconductor device according to embodiments may further include a second conductivity type doped layer positioned within the second conductivity type doped well region 133. The second conductivity type doped layer may be positioned on the side surface of the first conductivity type doped layer 135. The second conductivity type doped layer may be positioned between the source electrode 173 and the second conductivity type doped well region 133. The second conductivity doped layer may include SiC. For example, the second conductivity doped layer may include 4H SiC. The second conductivity doped layer may be p-type doped.

A semiconductor device according to embodiments may further include an interlayer insulating layer 140 positioned over the gate electrode 150.

The interlayer insulating layer 140 may be positioned on the first conductivity type semiconductor layer 131. The interlayer insulating layer 140 may be positioned over the gate electrode 150. Specifically, the interlayer insulating layer 140 may cover the upper surface and side surface of the gate electrode 150. The interlayer insulating layer 140 may cover the side surface of the gate insulating layer 151. The interlayer insulating layer 140 may also be positioned over at least a portion of the second conductivity type doped well region 133. The interlayer insulating layer 140 may have a lower surface that contacts at least a portion of an upper surface of the second conductivity type doped well region 133. The gate electrode 150 may be insulated from the source electrode 173 by the interlayer insulating layer 140.

The interlayer insulating layer 140 may include an insulating material. The interlayer insulating layer 140 may include the same insulating material as the gate insulating layer 151. For example, the interlayer insulating layer 140 may include SiO₂. However, example embodiments are not limited thereto, and the interlayer insulating layer 140 may include various types of insulating materials to insulate the gate electrode 150 from the source electrode 173. For example, the interlayer insulating layer 140 may include SiOC, SiN, SiON or a combination thereof. The interlayer insulating layer 140 may be composed of a single layer or multiple layers. When the interlayer insulating layer 140 is made of the same material as the gate insulating layer 151, the boundary between the interlayer insulating layer 140 and the gate insulating layer 151 may not be clearly distinguished at the portion where the interlayer insulating layer 140 and the gate insulating layer 151 come into contact.

The source electrode 173 may be positioned on the second conductivity type doped well region 133. The source electrode 173 may be positioned on the first conductivity type doped layer 135. The source electrode 173 may be electrically connected to the second conductivity type doped well region 133 through the first conductivity type doped layer 135.

The source electrode 173 of a semiconductor device according to embodiments may include a contact portion 173C positioned between the plurality of gate electrodes 150 spaced apart in the first direction (X direction).

The contact portion 173C may be positioned between the plurality of gate electrodes 150 spaced apart in the first direction (X direction). The contact portion 173C may refer to a portion of the source electrode 173 positioned between the plurality of gate electrodes 150 spaced apart in the first direction (X direction). The contact portion 173C may extend in a direction parallel to the gate electrode 150. The contact portion 173C may be positioned on the side surface of the gate electrode 150. The interlayer insulating layer 140 may be positioned between the contact portion 173C and the gate electrode 150. The contact portion 173C may be separated from the gate electrode 150 by the interlayer insulating layer 140. The contact portion 173C may come into contact with the side surface of the interlayer insulating layer 140.

The contact portion 173C may overlap with the second conductivity type doped well region 133 in the third direction (Z direction). For example, contact portion 173C may overlap a portion of the second conductivity type doped well region 133 in the third direction (Z direction). Additionally, the contact portion 173C may overlap with the pillar layer 300 in the third direction (Z direction). At least a portion of the contact portion 173C may overlap the first conductivity type doped layer 135 in the third direction (Z direction).

The source electrode 173 may include a conductive material. For example, the source electrode 173 may include a metal, a metal alloy, a conductive metal nitride, a metal silicide, a doped semiconductor material, a conductive metal oxide, or a conductive metal oxynitride. For example, the source electrode 173 may be selected from the group consisting of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbide nitride (TiAlC—N), titanium aluminum carbide (TiAlC), titanium carbide (TiC), tantalum carbide nitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), It may include, but example embodiments are not limited thereto, molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or combinations thereof. The source electrode 173 may be formed of a single layer or multiple layers.

A semiconductor device according to embodiments may further include a silicide layer 190 positioned between the source electrode 173 and the first conductivity type doped layer 135 and between the source electrode 173 and the second conductivity type doped well region 133.

The silicide layer 190 may be conformally positioned along the interface between the source electrode 173 and the first conductivity type doped layer 135 and between the source electrode 173 and the second conductivity type doped well region 133. The silicide layer 190 may be positioned between the contact portion 173C of the source electrode 173 and the second conductivity type doped well region 133. The lower surface of the silicide layer 190 may be in contact with the first conductivity type doped layer 135 and the second conductivity type doped well region 133. In embodiments, the lower surface of the silicide layer 190 may be in contact with the second conductivity type doped well region 133. The upper surface of the silicide layer 190 may contact the source electrode 173.

The silicide layer 190 may include a metal silicide material. For example, the silicide layer 190 may include tungsten silicide (WSi), titanium silicide (TiSi), cobalt silicide (CoSi), nickel silicide (NiSi), or a combination thereof.

The drain electrode 175 may be positioned on the second surface 110b of the substrate 110, i.e., the lower surface. The upper surface of the drain electrode 175 may be in contact with the lower surface of the substrate 110. The drain electrode 175 may be in ohmic contact with the substrate 110. The region in contact with the drain electrode 175 within the substrate 110 may be doped at a relatively high concentration compared to other regions. However, example embodiments are not limited thereto, and other layers may be additionally positioned between the drain electrode 175 and the substrate 110. For example, a silicide layer may be positioned between the drain electrode 175 and the substrate 110. The silicide layer may include a metal silicide material. The drain electrode 175 and the substrate 110 may be electrically well-connected by the metal silicide layer.

The drain electrode 175 may include a conductive material. For example, the drain electrode 175 may include a metal, a metal alloy, a conductive metal nitride, a metal silicide, a doped semiconductor material, a conductive metal oxide, or a conductive metal oxynitride. The drain electrode 175 may be made of the same material as the source electrode 173, or may be made of a different material. The drain electrode 175 may be formed of a single layer or multiple layers.

According to embodiments, a semiconductor device may cause a driving current to flow in a third direction (Z direction) from the source electrode 173 toward the drain electrode 175 when a turn-on signal is applied to the gate electrode 150. In this case, the driving current may reach the drain electrode 175 through the first conductivity type doped layer 135 from the source electrode 173, the second conductivity type doped well region 133 adjacent to the gate electrode 150, the first conductivity type semiconductor layer 131, and the substrate 110.

Hereinafter, with further reference to FIG. 2, pillar patterns 310 and 320 of a semiconductor device according to embodiments will be described in detail.

FIG. 2 is a graph illustrating the contents of materials constituting the pillar layer and the first conductivity type semiconductor layer of a semiconductor device according to embodiments. FIG. 2 shows the energy band gap and a content of the first element in the first pillar pattern 310, the second pillar pattern 320, and the first conductivity type semiconductor layer 131 along the first direction (X direction) from the reference axis CX extending in the third direction (Z direction) from the center portion of the pillar layer 300. Here, ‘content’ may mean atomic percent (at %).

As described above, the first conductivity type semiconductor layer 131, the second conductivity type doped well region 133, the first pillar pattern 310, and the second pillar pattern 320 of the semiconductor device according to embodiments may include the same material. For example, the first conductivity type semiconductor layer 131, the second conductivity type doped well region 133, the first pillar pattern 310, and the second pillar pattern 320 may include a first element that is a semiconductor element and a second element that is different from the first element. Here, the first element may be Si and the second element may be C, but example embodiments are not limited thereto. The first pillar pattern 310 and the second pillar pattern 320 may be SiₓC_{1-x (}0<x<1).

The first pillar pattern 310, the second pillar pattern 320, and the first conductivity type semiconductor layer 131 may include a material having a predetermined energy band gap. In this case, the energy band gap may be determined according to a content (at %) of the first element and the second element in the semiconductor material comprising the first pillar pattern 310, the second pillar pattern 320, and the first conductivity type semiconductor layer 131. Specifically, as the content (at %) of the first element, which is a semiconductor element, increases, the energy band gap tends to narrow. As the content (at %) of the second element increases, the energy band gap tends to widen. For example, the first pillar pattern 310 of the semiconductor device according to embodiments may include a material having a first energy band gap BE1, the second pillar pattern 320 may include a material having a second energy band gap BE2, and the first conductivity type semiconductor layer 131 may include a material having a third energy band gap BE3.

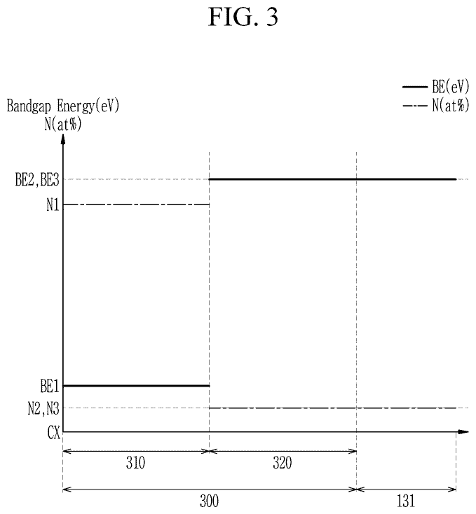

Referring further to FIG. 2, the pillar layer 300 may include portions having different energy band gaps. For example, the energy band gap of the semiconductor material at the center portion of the pillar layer 300 may be smaller than the energy band gap of the semiconductor material at the outer portion of the pillar layer 300. For example, the energy band gap of the semiconductor material constituting the pillar layer 300 may increase in a step-like manner as it moves away from the reference axis CX along the first direction (X direction). However, example embodiments are not limited thereto, and the energy band gap of the pillar layer 300 may be variously changed within a range that increases as it moves away from the reference axis CX in the first direction (X direction). A detailed description of this will be given later in FIGS. 3 to 7.

Specifically, the first energy band gap BE1 of the first pillar pattern 310 may be smaller than the second energy band gap BE2 of the second pillar pattern 320. The first energy band gap BE1 and the second energy band gap BE2 may have substantially constant sizes, but example embodiments are not limited thereto. Therefore, the energy band gap of the semiconductor material at the center portion of the pillar layer 300 may be smaller than the energy band gap of the semiconductor material at the outer portion of the pillar layer 300. The conductivity of the first pillar pattern 310 may be greater than the conductivity of the second pillar pattern 320.

According to embodiments, a content N1 of the first element in the first pillar pattern 310 may be different from a content N2 of the first element in the second pillar pattern 320. For example, since the energy band gap tends to narrow as the content of the first element, which is a semiconductor element, increases, the content N1 of the first element in the first pillar pattern 310 may be greater than the content N2 of the first element in the second pillar pattern 320. A content of the second element in the first pillar pattern 310 may be less than a content of the second element in the second pillar pattern 320. Here, the first element may be Si and the second element may be C, but example embodiments are not limited thereto.

Additionally, the second energy band gap BE2 of the second pillar pattern 320 may be smaller than the third energy band gap BE3 of the first conductivity type semiconductor layer 131. The second energy band gap BE2 and the third energy band gap BE3 may have substantially constant sizes, but example embodiments are not limited thereto. The conductivity of the second pillar pattern 320 may be greater than the conductivity of the first conductivity type semiconductor layer 131.

According to embodiments, the content N2 of the first element in the second pillar pattern 320 may be different from a content N3 of the first element in the first conductivity type semiconductor layer 131. For example, since the energy band gap tends to narrow as the content of the first element, which is a semiconductor element, increases, the content N2 of the first element in the second pillar pattern 320 may be greater than the content N3 of the first element in the first conductivity type semiconductor layer 131, but example embodiments are not limited thereto. The content of the second element in the second pillar pattern 320 may be less than a content of the second element in the first conductivity type semiconductor layer 131. Here, the first element may be Si and the second element may be C, but example embodiments are not limited thereto.

According to embodiments, the first conductivity type semiconductor layer 131 of the semiconductor device may have an n-type, and the pillar layer 300 may have a p-type. Additionally, the plurality of pillar layers 300 may be arranged to extend in the third direction (Z direction) and spaced apart along the first direction (X direction) within the first conductivity type semiconductor layer 131. Accordingly, the semiconductor device may form a superjunction in which the first conductivity type semiconductor layer 131 and the pillar layer 300 regions are completely depleted, and the electric field distribution is uniformly formed within the first conductivity type semiconductor layer 131 and the pillar layer 300.

In this case, in order for the semiconductor element to form a superjunction, holes must be able to move from the pillar layer 300 to the first conductivity type semiconductor layer 131, and this may be determined by the size of the energy barrier of the material layer. For example, the lower the energy barrier of a material layer, the lower the required activation energy, and the easier it is for holes to move into the material layer. Here, activation energy may mean the amount of energy required for a hole to be conducted into the valence band.

A semiconductor device according to embodiments may include a first pillar pattern 310 having a first energy band gap BE1 smaller than a third energy band gap BE3 of the first conductivity type semiconductor layer 131. Since the first pillar pattern 310 includes a material having a small energy band gap, the hole density within the first pillar pattern 310 may increase, and the region between the first conductivity type semiconductor layer 131 and the pillar layer 300 may be easily depleted.

Additionally, the pillar layer 300 of the semiconductor device according to embodiments may include a second pillar pattern 320 having a second energy band gap BE2 that is larger than the first energy band gap BE1 of the first pillar pattern 310 and smaller than a third energy band gap BE3 of the first conductivity type semiconductor layer 131. Accordingly, a relatively low-height energy barrier is formed between the first pillar pattern 310 and the second pillar pattern 320 and between the second pillar pattern 320 and the first conductivity type semiconductor layer 131, allowing holes to move easily. Accordingly, the regions of the first conductivity type semiconductor layer 131 and the pillar layer 300 may be easily depleted, so that a superjunction may be effectively formed, and the breakdown voltage of the semiconductor device according to embodiments may be increased and the on-resistance may be reduced. Accordingly, the reliability of a semiconductor device according to embodiments may be improved.

Additionally, the content N2 of the first element in the second pillar pattern 320 may be less than the content N1 of the first element in the first pillar pattern 310, and may be greater than the content N3 of the first element in the first conductivity type semiconductor layer 131. As the content of the first element sequentially increases along the first conductivity type semiconductor layer 131, the second pillar pattern 320, and the first pillar pattern 310, it is possible to prevent defects from occurring due to lattice constant differences at the interface between materials having different contents. Accordingly, the reliability of a semiconductor device according to embodiments may be improved.

Hereinafter, referring to FIG. 3 to 8, a pillar layer of a semiconductor device according to some embodiments will be described.

FIGS. 3 to 8 are graphs illustrating the contents of materials constituting a pillar layer and a first conductivity type semiconductor layer of a semiconductor device according to some embodiments.

FIGS. 3 to 8 illustrate various modifications of a semiconductor device according to embodiments illustrated in FIGS. 1 and 2. The embodiments illustrated in FIGS. 3 to 8 are substantially identical to the embodiments illustrated in FIGS. 1 and 2, so a description thereof will be omitted and the differences will be mainly described. Additionally, the same drawing symbols are used for the same components as in the previous embodiment.

Referring to FIGS. 1 and 3, the second energy band gap BE2 of the second pillar pattern 320 of the semiconductor device according to some embodiments may be substantially equal to the third energy band gap BE3 of the first conductivity type semiconductor layer 131. The second energy band gap BE2 and the third energy band gap BE3 may have substantially constant sizes, but example embodiments are not limited thereto. The conductivity of the second pillar pattern 320 may be substantially the same as, but example embodiments are not limited thereto, the conductivity of the first conductivity type semiconductor layer 131.

According to embodiments, the content N2 of the first element in the second pillar pattern 320 may be substantially equal to the content N3 of the first element in the first conductivity type semiconductor layer 131. The content of the second element in the second pillar pattern 320 may be substantially the same as the content of the second element in the first conductivity type semiconductor layer 131. Here, the first element may be Si and the second element may be C, but example embodiments are not limited thereto.

In embodiments of FIG. 3, the second energy band gap BE2 of the second pillar pattern 320 may be substantially the same as the third energy band gap BE3 of the first conductivity type semiconductor layer 131. In this case, the second pillar pattern 320 has a p-type and the first conductivity type semiconductor layer 131 has an n-type, so an energy barrier exists between the second pillar pattern 320 and the first conductivity type semiconductor layer 131. Therefore, compared to the case where the second pillar pattern 320 is not present, a relatively low-sized energy barrier is formed between the first pillar pattern 310 and the second pillar pattern 320 and between the second pillar pattern 320 and the first conductivity type semiconductor layer 131, allowing holes to move easily. Accordingly, the breakdown voltage of a semiconductor device according to embodiments may be increased and the on-resistance may be decreased. Accordingly, the reliability of a semiconductor device according to embodiments may be improved.

Referring to FIG. 1 and FIGS. 4 to 7, the content N1 of the first element in the first pillar pattern 310 of the semiconductor device according to some embodiments and the content N2 of the first element in the second pillar pattern 320 may have different values as they move away from the reference axis CX in the first direction (X direction). For example, the content N1 of the first element in the first pillar pattern 310 may decrease as it moves away from the reference axis CX in the first direction (X direction). The content N2 of the first element in the second pillar pattern 320 may decrease as it moves away from the reference axis CX in the first direction (X direction). The content N2 of the first element in the second pillar pattern 320 may decrease with increasing distance from the first pillar pattern 310.

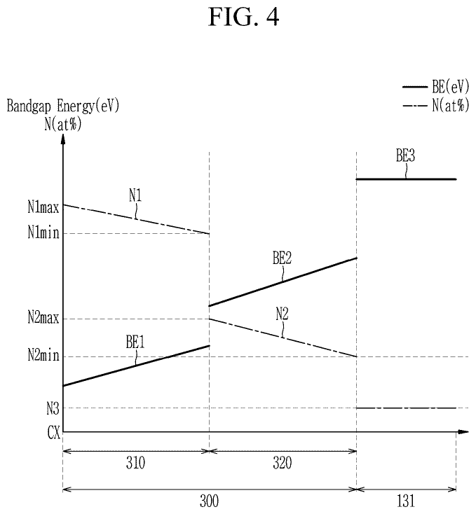

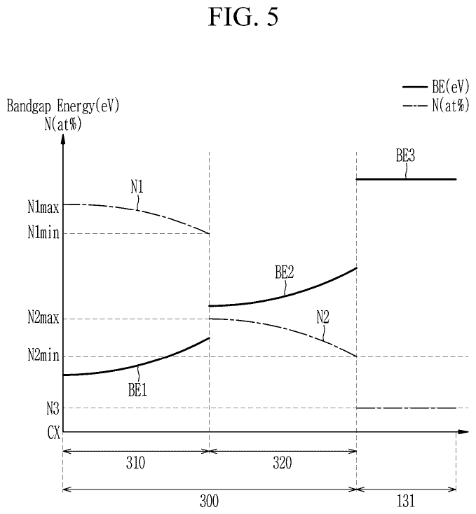

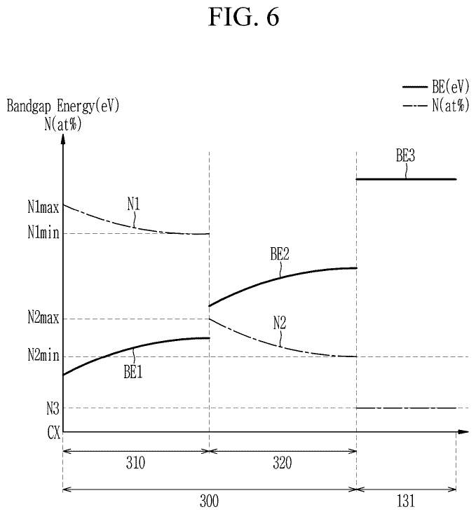

In this case, the change rate of the content N1 of the first element in the first pillar pattern 310 and the change rate of the content of the second element in the second pillar pattern 320 may be variously changed. For example, as illustrated in FIG. 4, the change rate of the content N1 of the first element in the first pillar pattern 310 and the change rate of the content of the second element in the second pillar pattern 320 may be constant. As another example, as illustrated in FIG. 5, the rate of change in the content N1 of the first element in the first pillar pattern 310 and the rate of change in the content of the second element in the second pillar pattern 320 may also increase. As another example, as illustrated in FIG. 6, the rate of change in the content N1 of the first element in the first pillar pattern 310 and the rate of change in the content of the second element in the second pillar pattern 320 may decrease. Here, the change rate of the content N1 of the first element in the first pillar pattern 310 and the change rate of the content of the second element in the second pillar pattern 320 may mean the change amount of the content according to the unit distance in the first direction (X direction) from the reference axis CX.

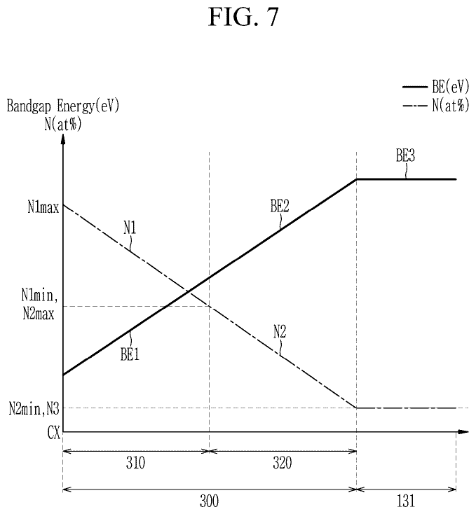

According to embodiments, the content N1 of the first element in the first pillar pattern 310 may have a maximum value N1max near the reference axis CX and a minimum value N1min in a portion adjacent to the second pillar pattern 320. Additionally, the content N2 of the first element in the second pillar pattern 320 may have a maximum value N2max in a portion adjacent to the first pillar pattern 310, and may have a minimum value N2min in a portion adjacent to the first conductivity type semiconductor layer 131. For example, as illustrated in FIGS. 4 to 6, the minimum value N1min of the content N1 of the first element in the first pillar pattern 310 may be greater than the maximum value N2max of the content N2 of the first element in the second pillar pattern 320. Additionally, the minimum value N2min of the content N2 of the first element in the second pillar pattern 320 may be greater than the content N3 of the first element in the first conductivity type semiconductor layer 131. However, example embodiments are not limited thereto, and as another example, as illustrated in FIG. 7, the minimum value N1min of the content N1 of the first element in the first pillar pattern 310 may be substantially equal to the maximum value N2max of the content N2 of the first element in the second pillar pattern 320. Additionally, the minimum value N2min of the content N2 of the first element in the second pillar pattern 320 may be substantially equal to the content N3 of the first element in the first conductivity type semiconductor layer 131.

Accordingly, the first energy band gap of the first pillar pattern 310 may gradually increase as it moves away from the reference axis CX along the first direction (X direction). The first energy band gap of the second pillar pattern 320 may gradually increase as it moves away from the reference axis CX along the first direction (X direction). Therefore, in the semiconductor devices according to the embodiments of FIGS. 4 to 7, an relatively low energy barrier may be continuously formed, and thus a depletion region may be formed more easily. Accordingly, the breakdown voltage of a semiconductor device according to embodiments may be increased and the on-resistance may be decreased. The reliability of a semiconductor device according to embodiments may be improved.

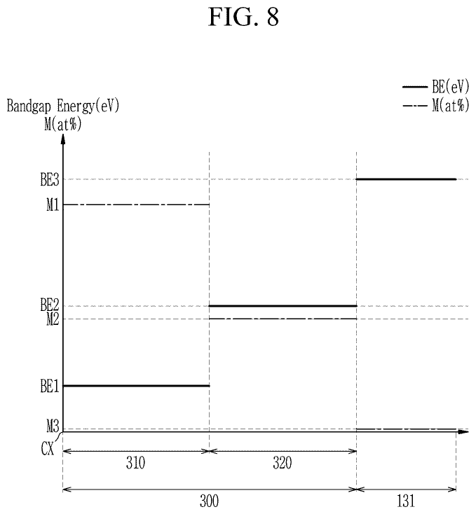

Referring to FIGS. 1 and 8, the first pillar pattern 310 and the second pillar pattern 320 of the semiconductor device according to some embodiments may further include a third element that is a semiconductor element different from the first element and the second element. Here, the first element may be Si, the second element may be C, and the third element may be Ge. For example, the first pillar pattern 310 and the second pillar pattern 320 may be SiₓGe_{y}C_{t-x-y} (0<x<1,0<y<1).

A content M1 of the third element in the first pillar pattern 310 may be greater than a content M2 of the third element in the second pillar pattern 320. In this case, the content of the first element in the first pillar pattern 310 may be substantially the same as the content of the second element in the first pillar pattern 310, but example embodiments are not limited thereto. Additionally, the content of the first element in the second pillar pattern 320 may be substantially the same as the content of the second element in the second pillar pattern 320, but example embodiments are not limited thereto.

In embodiments, the content of the second element in the first pillar pattern 310 may be less than the content of the second element in the second pillar pattern 320. The sum of the content of the first element in the first pillar pattern 310 and the content M1 of the third element may be greater than the sum of the content of the first element in the second pillar pattern 320 and the content M2 of the third element. In this range, the first energy band gap BE1 of the first pillar pattern 310 may be smaller than the second energy band gap BE2 of the second pillar pattern 320. For example, the content of the second element in the first pillar pattern 310 may be less than the content of the second element in the second pillar pattern 320, and the content of the first element in the first pillar pattern 310 may be less than or equal to the content of the first element in the second pillar pattern 320. In this case, the content M1 of the third element in the first pillar pattern 310 may be greater than the content M2 of the third element in the second pillar pattern 320, and the first energy band gap BE1 of the first pillar pattern 310 may be smaller than the second energy band gap BE2 of the second pillar pattern 320.

As another example, the content of the second element in the first pillar pattern 310 may be substantially equal to the content of the second element in the second pillar pattern 320. In this case, the content M1 of the third element in the first pillar pattern 310 may be greater than the content M2 of the third element in the second pillar pattern 320. In this range, the first energy band gap BE1 of the first pillar pattern 310 may be smaller than the second energy band gap BE2 of the second pillar pattern 320.

The content of the second element in the second pillar pattern 320 may be less than or equal to the content of the second element in the first conductivity type semiconductor layer 131. Accordingly, the second energy band gap BE2 of the second pillar pattern 320 may be smaller than the third energy band gap BE3 of the first conductivity type semiconductor layer 131.

In some embodiments, the first conductivity type semiconductor layer 131 may not include a third element. A content M3 of the third element in the first conductivity type semiconductor layer 131 may be approximately 0. However, example embodiments are not limited thereto, and the first conductivity type semiconductor layer 131 may further include a third element. In this case, the content M3 of the third element in the first conductivity type semiconductor layer 131 may be less than or equal to the content of the second element in the second pillar pattern 320.

In some embodiments, when the first pillar pattern 310 and the second pillar pattern 320 are composed of SiₓGe_{y}C_{1-x-y} (0<x<1, 0<y<1), the contents (at %) of the first element, the second element, and the third element of each of the first pillar pattern 310 and the second pillar pattern 320 may be variously changed within a range in which the first energy band gap BE1 of the first pillar pattern 310 is smaller than the second energy band gap BE2 of the second pillar pattern 320.

In embodiments of FIG. 8, the first element, the second element, and the third element constituting the first pillar pattern 310, the second pillar pattern 320, and the first conductivity type semiconductor layer 131 may be variously changed. For example, the first element may include the semiconductor element Ga, the second element may include N, and the third element may include In. The first conductivity type semiconductor layer 131 may include GaN, and the first pillar pattern 310 and the second pillar pattern 320 may include InGaN. For example, the first pillar pattern 310 and the second pillar pattern 320 may be In_{z}Ga_{1-z}N (0<z<1). Even in this case, the first energy band gap BE1 of the first pillar pattern 310 may be smaller than the second energy band gap BE2 of the second pillar pattern 320, and the second energy band gap BE2 of the second pillar pattern 320 may be smaller than or equal to the third energy band gap BE3 of the first conductivity type semiconductor layer 131. For example, a In content (at %) in the first pillar pattern 310 may be greater than a In content (at %) in the second pillar pattern 320. A N content (at %) in the first pillar pattern 310 may be less than or equal to a N content (at %) in the second pillar pattern 320.

Hereinafter, referring to FIG. 9 to 12, a description will be given of a pillar layer of a semiconductor device according to some embodiments.

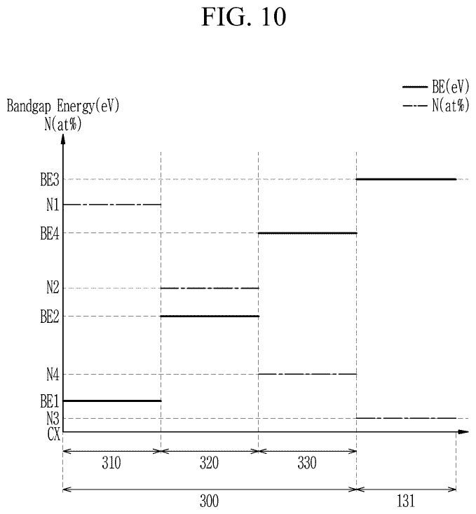

FIG. 9 is a cross-sectional view illustrating a semiconductor device according to some embodiments. FIGS. 10 to 12 are graphs showing the contents of materials constituting the pillar layer and the first conductivity type semiconductor layer of embodiments of FIG. 9.

FIGS. 9 to 12 illustrate various modifications of a semiconductor device according to embodiments illustrated in FIGS. 1 to 8. The embodiments illustrated in FIGS. 9 to 12 are substantially identical to the embodiments illustrated in FIGS. 1 to 8, so a description thereof will be omitted and the differences will be mainly explained. Additionally, the same drawing symbols are used for the same components as in the previous embodiment.

Referring to FIG. 9, the pillar layer 300 of the semiconductor device according to some embodiments may further include a third pillar pattern 330 positioned between the second pillar pattern 320 and the first conductivity type semiconductor layer 131.

The third pillar pattern 330 may be positioned on the side surface of the second pillar pattern 320. For example, the third pillar pattern 330 may be positioned on opposite side surfaces of the second pillar pattern 320, but example embodiments are not limited thereto. Opposite side surfaces of the third pillar pattern 330 may be covered by the second pillar pattern 320. The side surface of the third pillar pattern 330 may be in contact with the first conductivity type semiconductor layer 131, but example embodiments are not limited thereto.

The third pillar pattern 330 may be positioned between the substrate 110 and the second conductivity type doped well region 133. The third pillar pattern 330 may overlap with the second conductivity type doped well region 133 in the third direction (Z direction) and may not overlap with the gate electrode 150 in the third direction (Z direction). The third pillar pattern 330 may be positioned spaced apart from the substrate 110 in the third direction (Z direction). The upper surface of the third pillar pattern 330 may be in contact with the second conductivity type doped well region 133, but example embodiments are not limited thereto. The lower surface of the third pillar pattern 330 may be in contact with the first conductivity type semiconductor layer 131, but example embodiments are not limited thereto.

The third pillar pattern 330 may include a semiconductor material. The third pillar pattern 330 may include the same material as the first pillar pattern 310 and the second pillar pattern 320. For example, the third pillar pattern 330 may include a first element and a second element. Here, the first element may be Si and the second element may be C, but example embodiments are not limited thereto. For example, the first pillar pattern 310, the second pillar pattern 320, and the third pillar pattern 330 may be SiₓC_{1-x (}0<x<1).

Referring to FIG. 10, the fourth energy band gap BE4 of the third pillar pattern 330 may be larger than the second energy band gap BE2 of the second pillar pattern 320. The conductivity of the third pillar pattern 330 may be less than the conductivity of the second pillar pattern 320. A content N4 of the first element in the third pillar pattern 330 may be different from the content N2 of the first element in the second pillar pattern 320. For example, since the energy band gap tends to narrow as the content of the first element, which is a semiconductor element, increases, the content N4 of the first element in the third pillar pattern 330 may be smaller than the content N2 of the first element in the second pillar pattern 320. A content of the second element in the third pillar pattern 330 may be greater than the content of the second element in the second pillar pattern 320.

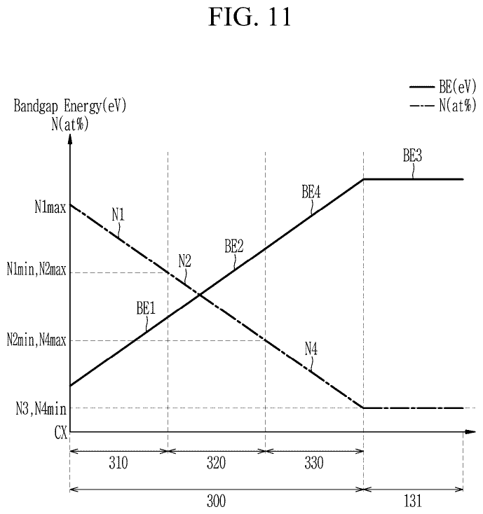

Referring to FIG. 11, the maximum value N4max of the content N4 of the first element in the third pillar pattern 330 may be substantially equal to the minimum value N2min of the content N2 of the first element in the second pillar pattern 320. Additionally, the minimum value N4min of the content N4 of the first element in the third pillar pattern 330 may be substantially equal to the content N3 of the first element in the first conductivity type semiconductor layer 131.

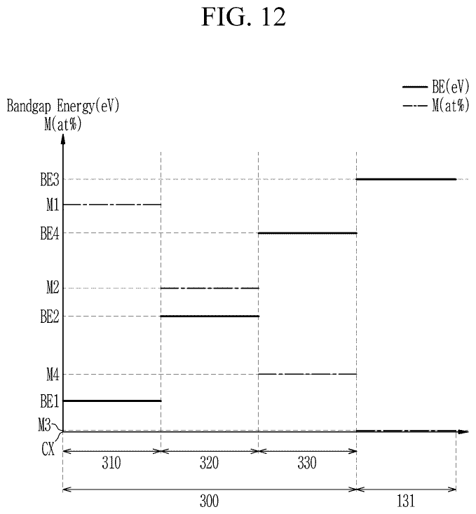

Referring to FIG. 12, the first pillar pattern 310, the second pillar pattern 320, and the third pillar pattern 330 may further include a third element that is a semiconductor element different from the first element and the second element. Here, the first element may be Si, the second element may be C, and the third element may be Ge. For example, the first pillar pattern 310, the second pillar pattern 320, and the third pillar pattern 330 may be SiₓGe_{y}C_{1-x-y} (0<x<1, 0<y<1).

A content M4 of the third element in the third pillar pattern 330 may be less than the content M2 of the third element in the second pillar pattern 320. In this case, the content of the first element in the third pillar pattern 330 may be substantially the same as the content of the second element in the third pillar pattern 330, but example embodiments are not limited thereto.

In embodiments, the content of the second element in the third pillar pattern 330 may be greater than or equal to the content of the second element in the second pillar pattern 320. The sum of the content of the first element in the third pillar pattern 330 and the content M4 of the third element may be less than or equal to the sum of the content of the first element in the second pillar pattern 320 and the content M2 of the third element. In this range, the fourth energy band gap BE4 of the third pillar pattern 330 may be larger than the second energy band gap BE2 of the second pillar pattern 320. The content of the second element in the third pillar pattern 330 may be less than or equal to the content of the second element in the first conductivity type semiconductor layer 131.

In some embodiments, when the first pillar pattern 310, the second pillar pattern 320, and the third pillar pattern 330 are composed of SiₓGe_{y}C_{1-x-y} (0<x<1, 0<y<1), the contents (at %) of the first element, the second element, and the third element of each of the first pillar pattern 310, the second pillar pattern 320, and the third pillar pattern 330 may be variously changed within a range in which the first energy band gap BE1 of the first pillar pattern 310 is smaller than the second energy band gap BE2 of the second pillar pattern 320, and the second energy band gap BE2 of the second pillar pattern 320 is smaller than the fourth energy band gap BE4 of the third pillar pattern 330.

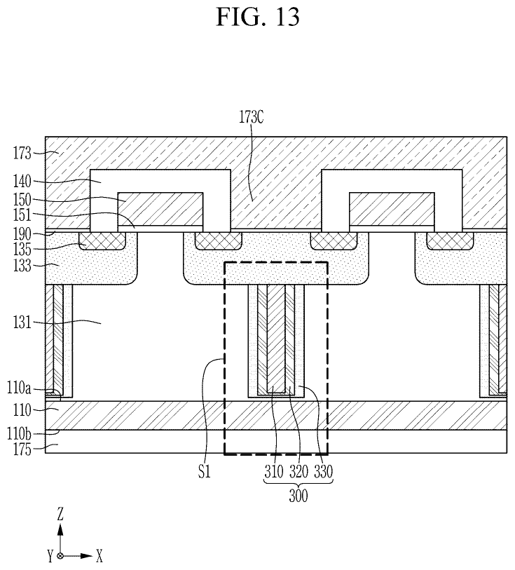

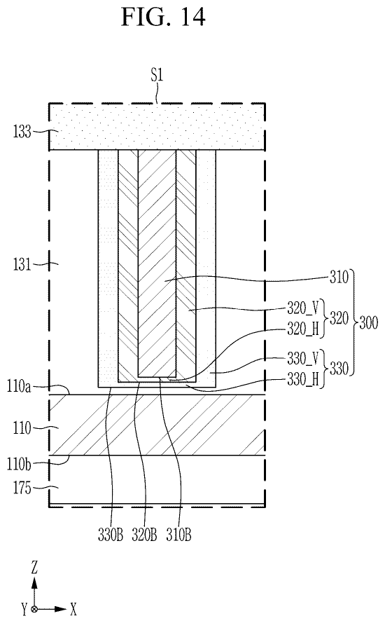

Hereinafter, referring to FIGS. 13 and 14, a description will be given of a pillar layer of a semiconductor device according to some embodiments.

FIG. 13 is a cross-sectional view illustrating a semiconductor device according to some embodiments. FIG. 14 is an enlarged cross-sectional view of the SI area of FIG. 13.

FIGS. 13 and 14 illustrate various modifications of a semiconductor device according to embodiments illustrated in FIGS. 9 to 12. The embodiments illustrated in FIGS. 13 and 14 are substantially identical to the embodiments illustrated in FIGS. 9 to 12, so a description thereof will be omitted and the differences will be mainly described. Additionally, the same drawing symbols are used for the same components as in the previous embodiment.

Referring to FIGS. 13 and 14, the second pillar pattern 320 may include a vertical portion 320_V extending in a third direction (Z direction) from the lower surface of the second conductivity type doped well region 133 toward the substrate 110 and a horizontal portion 320_H positioned on the lower surface 310B of the first pillar pattern 310.

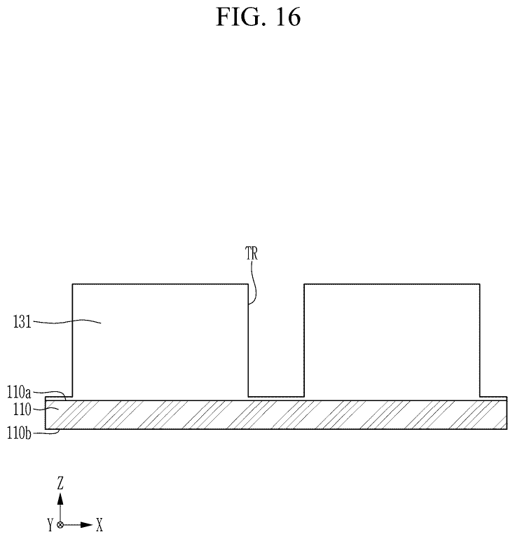

The vertical portion 320_V may be positioned on the side surface of the first pillar pattern 310. The vertical portion 320_V may extend in the third direction (Z direction). The horizontal portion 320_H may be extended in the first direction (X direction). The horizontal portion 320_H may be positioned spaced apart from the substrate 110 in the third direction (Z direction). The thickness of the horizontal portion 320_H along the third direction (Z direction) may be smaller than the thickness of the vertical portion 320_V along the first direction (X direction). For example, the thickness of the horizontal portion 320_H in the third direction (Z direction) may be 1/500 to 1/10 of the thickness of the vertical portion 320_V in the first direction (X direction). For example, the thickness along the third direction (Z direction) of the horizontal portion 320_H may be less than about 10 nm. Preferably, the thickness along the third direction (Z direction) of the horizontal portion 320_H may be about 2 nm or less. This may be due to a process characteristic in which a portion of the second pillar pattern material layer 320P is not removed on the bottom surface of the trench (see TR of FIG. 16) during the process of forming the second pillar pattern 320.

Accordingly, the second pillar pattern 320 may cover opposite side surfaces and the lower surface 310B of the first pillar pattern 310. The lower surface of the first pillar pattern 310 may be positioned spaced apart from the first conductivity type semiconductor layer 131 in the third direction (Z direction).

Additionally, the third pillar pattern 330 may include a vertical portion 330_V extending in the third direction (Z direction) from the lower surface of the second conductivity type doped well region 133 toward the substrate 110 and a horizontal portion 330_H positioned on the lower surface 320B of the second pillar pattern 320. In this case, the thickness of the horizontal portion 330_H in the third direction (Z direction) may be smaller than the thickness of the vertical portion 330_V in the first direction (X direction).

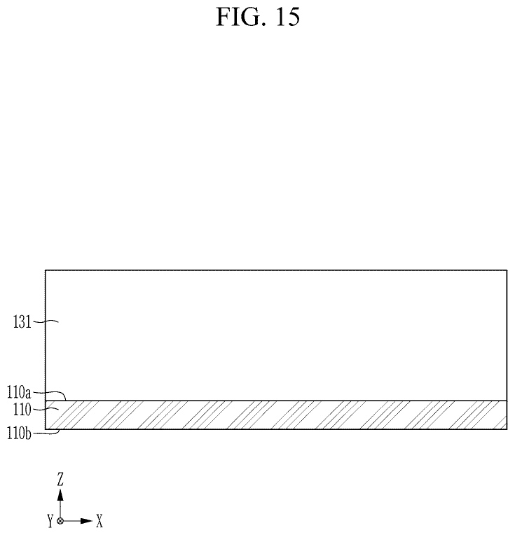

Hereinafter, a method for manufacturing a semiconductor device according to embodiments will be described, with referring to FIGS. 15 to 23.

FIGS. 15 to 23 are intermediate process cross-sectional views showing a method for manufacturing a semiconductor device according to embodiments.

Referring to FIG. 15, a first conductivity type semiconductor layer 131 may be formed on the substrate 110.

The substrate 110 may be a semiconductor substrate including SiC. For example, the substrate 110 may be made of a 4H SiC substrate. In some cases, the substrate 110 may be made of a 3C SiC substrate, a 6H SiC substrate, etc. The substrate 110 may be doped with first conductivity type impurities. For example, the first conductivity type impurity may be an n-type impurity. In other words, the substrate 110 may be doped as n-type. The substrate 110 may be heavily doped as n-type. The resistivity of the substrate 110 may be between about 0.005 Ωcm and about 0.035 Ωcm. The thickness of the substrate 110 may be from about 10 μm to about 700 μm. The material, doping type, doping concentration, resistivity, thickness, etc. of the substrate 110 are not limited thereto and may be variously changed.

The substrate 110 may include a first surface 110a and a second surface 110b opposing one another. For example, the first surface 110a of the substrate 110 may mean the upper surface of the substrate 110, and the second surface 110b of the substrate 110 may mean the lower surface of the substrate 110.

The first conductivity type semiconductor layer 131 may be formed on the substrate 110. The first conductivity type semiconductor layer 131 may be positioned on the first surface 110a of the substrate 110, i.e., the upper surface. The lower surface of the first conductivity type semiconductor layer 131 may be in contact with the first surface 110a of the substrate 110. However, example embodiments are not limited thereto, and other layers may be additionally positioned between the substrate 110 and the first conductivity type semiconductor layer 131. The first conductivity type semiconductor layer 131 may be an epitaxial layer formed from the substrate 110 using an epitaxial growth method. The first conductivity type semiconductor layer 131 may include SiC. For example, the first conductivity type semiconductor layer 131 may include 4H SiC. The first conductivity type semiconductor layer 131 may be doped as n-type. The first conductivity type semiconductor layer 131 may be lightly doped as n-type. The doping concentration of the first conductivity type semiconductor layer 131 may be lower than the doping concentration of the substrate 110. The doping concentration of the first conductivity type semiconductor layer 131 may be about 1*10¹⁵ cm⁻³ or more and about 1*10¹⁷ cm⁻³ or less. The thickness of the first conductivity type semiconductor layer 131 may be about 1 μm or more and about 13 μm or less.

Referring to FIG. 16, a trench TR may be formed within the first conductivity type semiconductor layer 131. The trench TR may extend along the third direction (Z direction). The bottom surface and inner sidewall of the trench TR may be defined by the first conductivity type semiconductor layer 131. The bottom surface (TR_B) of the trench TR may be spaced apart from the first surface 110a of the substrate 110. The trench TR may be an area where the pillar layer 300 is formed.

A semiconductor device according to embodiments may include a plurality of trenches TR arranged spaced apart along a first direction (X direction). The plurality of trenches TR may be spaced along the first direction (X direction). The depth of each of the plurality of trenches TR in the third direction (Z direction) may be the same, but example embodiments are not limited thereto.

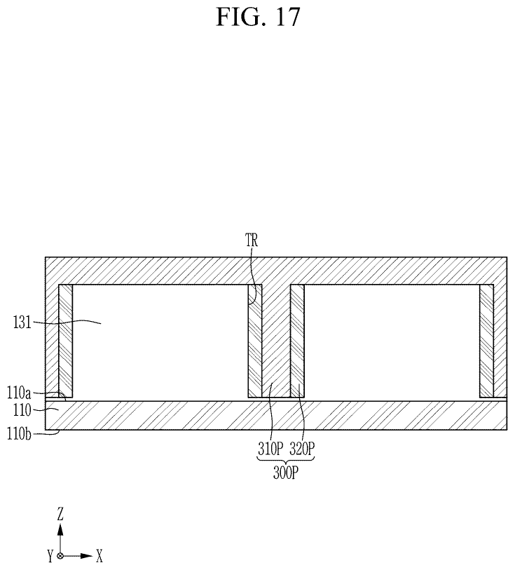

Referring to FIGS. 17, 18A, 18B, and 19, a pillar layer 300 may be formed including a second pillar pattern 320 including a semiconductor material having a second energy band gap and a first pillar pattern 310 including a semiconductor material having a first energy band gap within a trench TR.

Referring to FIG. 17, first, the second pillar pattern material layer 320P may be formed within the trench TR. The second pillar pattern material layer 320P may be formed using an epitaxial growth method using the first conductivity type semiconductor layer 131 as a seed. For example, the second pillar pattern material layer 320P may be formed using lateral epitaxial growth. Accordingly, the second pillar pattern material layer 320P may be formed along a horizontal direction (e.g., the first direction (X direction) and/or the second direction (Y direction)). The second pillar pattern material layer 320P may be formed from the first conductivity type semiconductor layer 131 portion defining the inner wall of the trench TR. The second pillar pattern material layer 320P may extend in the third direction (Z direction). The second pillar pattern material layer 320P may be conformally formed along the inner wall of the trench TR. The second pillar pattern material layer 320P may be positioned on the inner wall of the trench TR. The second pillar pattern material layer 320P may be positioned on the bottom surface of the trench TR, but example embodiments are not limited thereto.

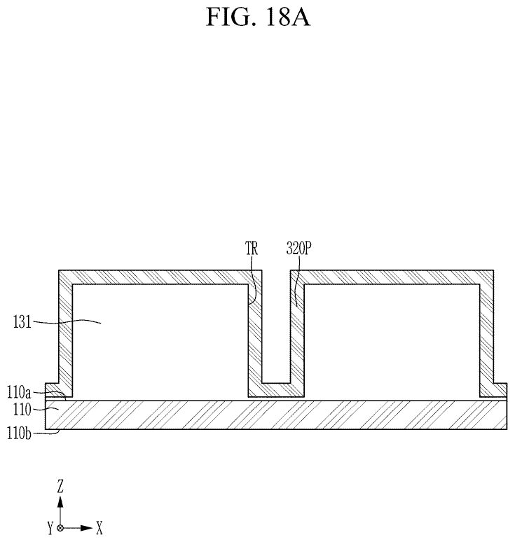

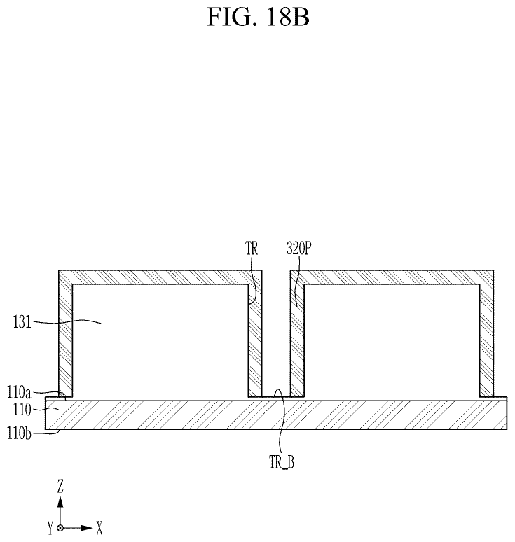

Although FIG. 17 describes the formation of the second pillar pattern material layer 320P using lateral epitaxial growth, it is not limited thereto. For example, as illustrated in FIG. 18A, the second pillar pattern material layer 320P may be formed on the inner wall and bottom surface of the trench TR using isotropic epitaxial growth. In this case, the second pillar pattern material layer 320P may be formed on the inner wall and bottom surface of the trench TR and the upper surface of the first conductivity type semiconductor layer 131. Next, as illustrated in FIG. 18B, at least a portion of the second pillar pattern material layer 320P may be removed to expose the bottom surface of the trench TR. The process of removing at least a portion of the second pillar pattern material layer 320P may be performed using, but example embodiments are not limited thereto, a dry etching process.

The second pillar pattern material layer 320P may include a semiconductor material. The second pillar pattern material layer 320P may include the same material as the first pillar pattern 310. The second pillar pattern material layer 320P may include the same material as the first conductivity type semiconductor layer 131 and the second conductivity type doped well region 133. For example, the second pillar pattern material layer 320P may include a first element and a second element. Here, the first element may be Si and the second element may be C, but example embodiments are not limited thereto. In this case, the semiconductor material constituting the second pillar pattern material layer 320P may have a second energy band gap (see BE2 of FIG. 2).

Next, a first pillar pattern material layer 310P may be formed to fill the trench TR. The first pillar pattern material layer 310P may fill the trench TR portion remaining after the second pillar pattern material layer 320P is formed. The first pillar pattern material layer 310P may be positioned on the first conductivity type semiconductor layer 131.

The first pillar pattern material layer 310P may include a semiconductor material. The first pillar pattern material layer 310P may include the same material as the first conductivity type semiconductor layer 131 and the second conductivity type doped well region 133. For example, the first pillar pattern material layer 310P may include a first element and a second element. Here, the first element may be Si and the second element may be C, but example embodiments are not limited thereto. In this case, the semiconductor material constituting the first pillar pattern material layer 310P may have the first energy band gap (see BE1 of FIG. 2).

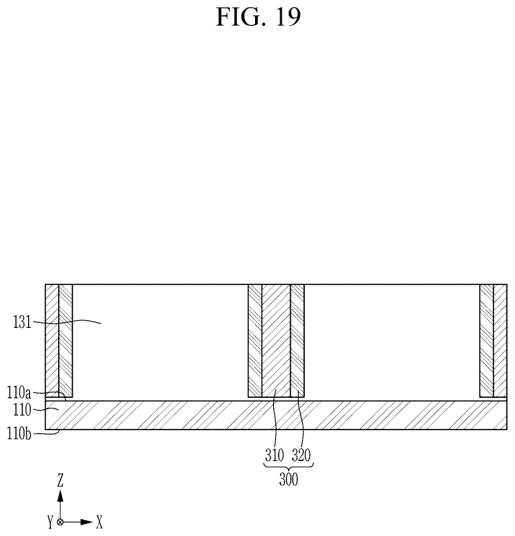

Referring to FIG. 19, a planarization process is performed to remove a portion of the first pillar pattern material layer 310P positioned on the upper surface of the first conductivity type semiconductor layer 131, thereby forming a first pillar pattern 310, and a portion of the second pillar pattern material layer 320P positioned on the upper surface of the first conductivity type semiconductor layer 131 is removed, thereby forming a second pillar pattern 320. Accordingly, the pillar layer 300 including the first pillar pattern 310 and the second pillar pattern 320 may be formed.

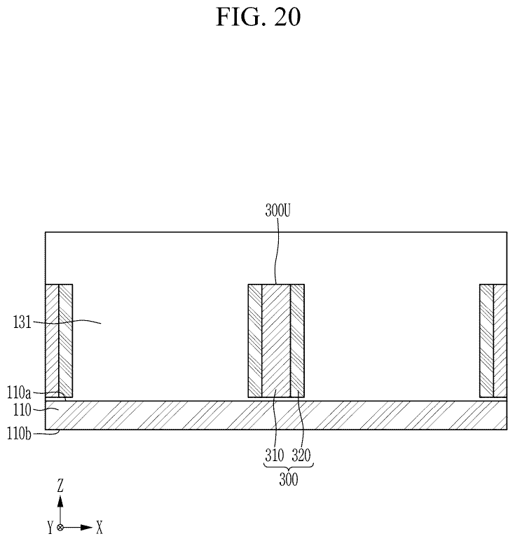

Referring to FIG. 20, a first conductivity type semiconductor layer 131 may be further formed on the pillar layer 300. Accordingly, the upper surface 300U of the pillar layer 300 may be covered by the first conductivity type semiconductor layer 131. The pillar layer 300 may be embedded within the first conductivity type semiconductor layer 131.

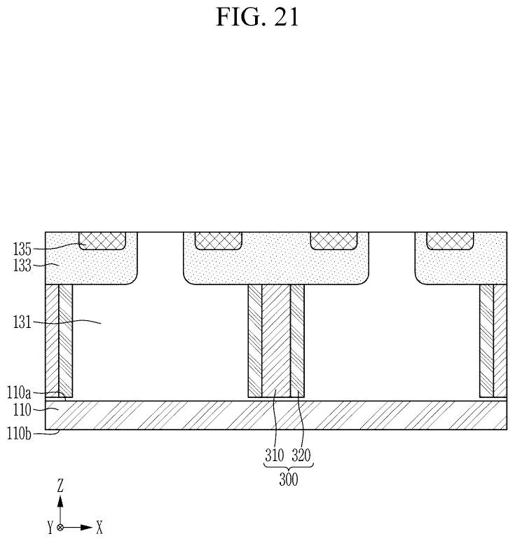

Referring to FIG. 21, first, a second conductivity type doped well region 133 may be formed on the pillar layer 300. The second conductivity type doped well region 133 may be positioned within the first conductivity type semiconductor layer 131. The second conductivity type doped well region 133 may be positioned on top of the first conductivity type semiconductor layer 131. The second conductivity type doped well region 133 may extend from the upper surface of the first conductivity type semiconductor layer 131 toward the lower surface of the first conductivity type semiconductor layer 131. The second conductivity type doped well region 133 may extend in the third direction (Z direction) from the upper surface of the first conductivity type semiconductor layer 131. The second conductivity type doped well region 133 may be formed in at least a portion of the first conductivity type semiconductor layer 131 by ion implantation, but example embodiments are not limited thereto.

Next, a first conductivity type doped layer 135 may be formed within the second conductivity type doped well region 133. The first conductivity type doped layer 135 may be positioned on top of the first conductivity type semiconductor layer 131. The first conductivity type doped layer 135 may be buried within the second conductivity type doped well region 133.

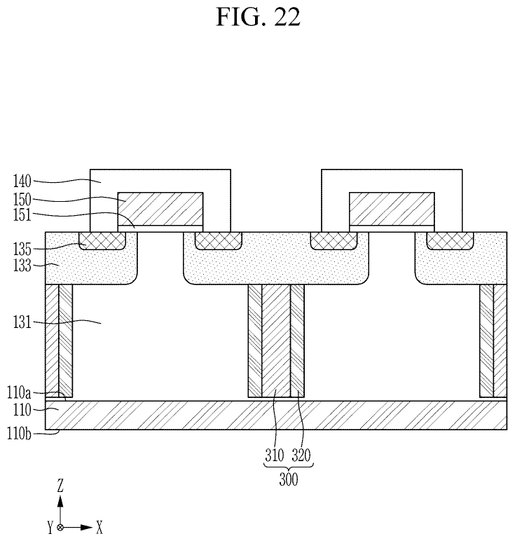

Referring to FIG. 22, a gate insulating layer 151 and a gate electrode 150 may be formed on the first conductivity type semiconductor layer 131.

The gate insulating layer 151 may be formed on the first conductivity type semiconductor layer 131. The thickness of the gate insulating layer 151 may be almost constant. In embodiments, the gate insulating layer 151 may overlap the second conductivity type doped well region 133 in the third direction (Z direction). The lower surface of the gate insulating layer 151 may be in contact with the second conductivity type doped well region 133, but example embodiments are not limited thereto.

The gate electrode 150 may be positioned on the gate insulating layer 151. The gate electrode 150 may be positioned on the first conductivity type semiconductor layer 131. The gate electrode 150 may be spaced apart from the first conductivity type semiconductor layer 131. For example, the gate electrode 150 may be spaced apart from the first conductivity type semiconductor layer 131 in the third direction (Z direction) by the gate insulating layer 151. A semiconductor device according to embodiments may have a planar-shaped gate structure. In the semiconductor device according to embodiments, the gate electrode 150 has a flat plate shape with an upper surface and a lower surface, and the lower surface of the gate electrode 150 may be positioned at a level higher than the uppermost surface of the first conductivity type semiconductor layer 131. However, example embodiments are not limited thereto, and the semiconductor device according to embodiments may have a trench-shaped gate structure. For example, in a semiconductor device according to embodiments, a trench having a predetermined depth is formed in a first conductivity type semiconductor layer 131, and the gate electrode 150 may be positioned inside the trench spaced apart from the first conductivity type semiconductor layer 131 in a third direction (Z direction). Additionally, the gate electrode 150 may be positioned spaced apart from the first conductivity type semiconductor layer 131 in the first direction (X direction). The gate electrode 150 may overlap the second conductivity type doped well region 133 in the third direction (Z direction).

A method for manufacturing a semiconductor device according to embodiments may further form an interlayer insulating layer 140 over the gate electrode 150. The interlayer insulating layer 140 may be positioned on the first conductivity type semiconductor layer 131. The interlayer insulating layer 140 may be positioned over the gate electrode 150. Specifically, the interlayer insulating layer 140 may cover the upper surface and side surface of the gate electrode 150. The interlayer insulating layer 140 may cover the side surface of the gate insulating layer 151. The interlayer insulating layer 140 may also be positioned over at least a portion of the second conductivity type doped well region 133. The interlayer insulating layer 140 may have a lower surface that contacts at least a portion of an upper surface of the second conductivity type doped well region 133.

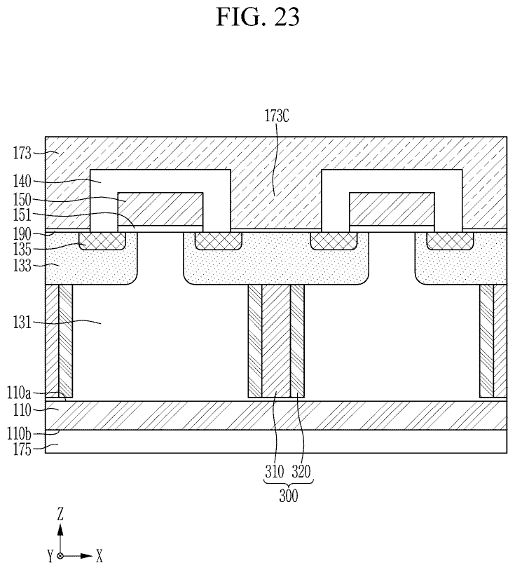

Referring to FIG. 23, a source electrode 173 may be formed on the second conductivity type doped well region 133, and a drain electrode 175 may be formed on the second surface 110b of the substrate 110.

The source electrode 173 may be positioned on the first conductivity type doped layer 135. The source electrode 173 may be electrically connected to the second conductivity type doped well region 133 through the first conductivity type doped layer 135. The upper surface of the drain electrode 175 may be in contact with the lower surface of the substrate 110. The drain electrode 175 may be in ohmic contact with the substrate 110. Accordingly, a semiconductor device according to embodiments may be formed.

Although the embodiments have been described in detail above, the scope of the present invention is not limited thereto, and various modifications and improvements made by those skilled in the art using the basic concept of the present invention defined in the following claims also fall within the scope of the present invention.

What is claimed is:

1. A semiconductor device comprising:
a substrate including a first surface and a second surface opposing one another;
a first conductivity type semiconductor layer positioned on the first surface of the substrate;
a second conductivity type doped well region positioned within the first conductivity type semiconductor layer;
a pillar layer positioned between the substrate and the second conductivity type doped well region and having the second conductivity type;
a gate electrode positioned on the first conductivity type semiconductor layer;
a gate insulating layer positioned between the first conductivity type semiconductor layer and the gate electrode;
a source electrode positioned on the second conductivity type doped well region; and
a drain electrode positioned on the second surface of the substrate,
wherein the pillar layer includes:
a first pillar pattern including a semiconductor material having a first energy band gap, and
a second pillar pattern positioned between the first pillar pattern and the first conductivity type semiconductor layer, the second pillar pattern including a semiconductor material having a second energy band gap greater than the first energy band gap.

2. The semiconductor device of claim 1,
wherein the first conductivity type semiconductor layer includes a material having a third energy band gap that is greater than or equal to the second energy band gap.

3. The semiconductor device of claim 1,
wherein the pillar layer is spaced apart from the substrate.

4. The semiconductor device of claim 3,
wherein the pillar layer overlaps the second conductivity type doped well region and does not overlap the gate electrode.

5. The semiconductor device of claim 1, wherein:
the first pillar pattern and the second pillar pattern extend from the lower surface of the second conductivity type doped well region toward the substrate, and
the lower surface of the first pillar pattern is in contact with the first conductivity type semiconductor layer.

6. The semiconductor device of claim 1, wherein:
the first pillar pattern and the second pillar pattern include a first element and a second element, and
a content (at %) of the first element in the first pillar pattern is greater than a content (at %) of the first element in the second pillar pattern.

7. The semiconductor device of claim 6, wherein:
the first conductivity type semiconductor layer includes the first element and the second element, and
the content (at %) of the first element in the second pillar pattern is greater than or equal to a content (at %) of the first element in the first conductivity type semiconductor layer.

8. The semiconductor device of claim 6,
wherein the content (at %) of the first element in the second pillar pattern decreases with increasing distance from the first pillar pattern.

9. The semiconductor device of claim 6,
wherein the first element includes Si and the second element includes C.

10. The semiconductor device of claim 1,
wherein:
the first conductivity type semiconductor layer includes a first element and a second element,
the second pillar pattern includes the first element, the second element, and a third element that is different from the first element and the second element, and
a content (at %) of the second element in the second pillar pattern is less than or equal to a content (at %) of the second element in the first conductivity type semiconductor layer.

11. The semiconductor device of claim 10,
wherein the first element includes Si, the second element includes C, and the third element includes Ge.

12. The semiconductor device of claim 10,
wherein:
the first pillar pattern includes the first element which is semiconductor element, the second element, and the third element, and
a content (at %) of the third element in the first pillar pattern is greater than a content (at %) of the third element in the second pillar pattern.

13. The semiconductor device of claim 10,
wherein a content (at %) of the first element in the second pillar pattern is the same as the content (at %) of the second element in the second pillar pattern.

14. The semiconductor device of claim 1, wherein the second pillar pattern includes:
a vertical portion extending from the lower surface of the second conductivity type doped well region toward the substrate, and
a horizontal portion positioned on the lower surface of the first pillar pattern, and
wherein a thickness of the horizontal portion is smaller than a thickness of the vertical portion.

15. The semiconductor device of claim 14,
wherein the thickness of the horizontal portion is 1/500 to 1/10 of the width of the pillar layer.

16. A semiconductor device comprising:
a substrate including a first surface and a second surface opposing one another;
a first conductivity type semiconductor layer positioned on the first surface of the substrate and including a first element that is a semiconductor material and a second element that is different from the first element;
a second conductivity type doped well region positioned within the first conductivity type semiconductor layer;
a pillar layer positioned within the first conductivity type semiconductor layer and extending from the lower surface of the second conductivity type doped well region toward the substrate, the pillar layer having the second conductivity type and including the first element and the second element;
a gate electrode positioned on the first conductivity type semiconductor layer;
a gate insulating layer positioned between the first conductivity type semiconductor layer and the gate electrode;
a source electrode positioned on the second conductivity type doped well region; and
a drain electrode positioned on the second surface of the substrate,
the pillar layer includes
a first pillar pattern, and
a second pillar pattern positioned between the first pillar pattern and the first conductivity semiconductor layer,
wherein a content (at %) of the second element in the second pillar pattern is greater than a content (at %) of the second element in the first pillar pattern.

17. The semiconductor device of claim 16,
wherein the content (at %) of the second element in the second pillar pattern is less than or equal to a content (at %) of the second element in the first conductivity type semiconductor layer.

18. The semiconductor device of claim 17, wherein:
the first pillar pattern and the second pillar pattern further include a third element, which is a semiconductor material different from the first element, and
a content (at %) of the third element in the second pillar pattern is smaller than a content (at %) of the third element in the first pillar pattern.

19. The semiconductor device of claim 16,
wherein the first element includes Si and the second element includes C.

20. A semiconductor device comprising:
a substrate including a first surface and a second surface opposing one another;
a first conductivity type semiconductor layer including Si and C, positioned on the first surface of the substrate;
a second conductivity type doped well region positioned within the first conductivity type semiconductor layer;
a pillar layer positioned between the substrate and the second conductivity type doped well region, the pillar layer having the second conductivity type and including Si and C;
a gate electrode positioned on the first conductivity type semiconductor layer;
a gate insulating layer positioned between the first conductivity type semiconductor layer and the gate electrode;
a source electrode positioned on the second conductivity type doped well region; and
a drain electrode positioned on the second surface of the substrate,
wherein the pillar layer includes:
a first pillar pattern including Si at a first content (at %), and
a second pillar pattern positioned between the first pillar pattern and the first conductivity type semiconductor layer, the second pillar pattern including Si at a second content (at %) smaller than the first content (at %),
wherein the second content (at %) in the second pillar pattern is greater than or equal to the Si content (at %) of the first conductivity type semiconductor layer.
